(19) United States
(12) Patent Application Publication
(10) Pub. No.: US 2010/0078811 A1
(43) Pub. Date: Apr. 1, 2010

(54) METHOD OF PRODUCING SEMICONDUCTOR DEVICES

(75) Inventor: Georg Meyer-Berg, Munich (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies AG, Neubiberg (DE)

(21) Appl. No.: 12/242,069

(22) Filed: Sep. 30, 2008

(51) Int. Cl. H01L 23/48; H01L 21/02; H01L 23/28

(52) U.S. Cl. 257/738; 438/114; 257/787; 257/E23.021; 257/E23.116; 257/E21.599

(57) ABSTRACT

A method of producing semiconductor devices. One embodiment provides producing at least two semiconductor chips. An encapsulation material is applied to the at least two semiconductor chips to form an encapsulation layer. The at least two semiconductor chips are separated from each other to obtain at least two separated semiconductor devices. The outline of each one of the semiconductor devices includes three corners in total or more than four corners.

### BACKGROUND

The present invention relates to a method of producing semiconductor devices, a method of producing units, a semiconductor device, and a semiconductor chip.

For producing semiconductor devices, a plurality of chips is provided, and the chips are embedded in an encapsulation material to form an embedded wafer. Afterwards the semiconductor chips are separated from each other to obtain a respective plurality of semiconductor devices. For separating the semiconductor chips from each other, the embedded wafer can, for example, be sawn so that the sawing lines form boundaries of the semiconductor devices obtained.

For these and other reasons there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a flow diagram of one embodiment of a method of producing at least two semiconductor devices.

FIG. 2A-C illustrate schematic representations of intermediate products and semiconductor devices for illustrating one embodiment of the embodiment as illustrated in FIG. 1.

FIG. 3 illustrates a flow diagram of one embodiment of a method of producing at least two semiconductor devices.

FIG. 4A-D illustrate schematic representations of intermediate products and semiconductor devices for illustrating one embodiment of the embodiment as illustrated in FIG. 3.

FIG. 5 illustrates a flow diagram of one embodiment of a method of producing at least two units;

FIG. 6A-C illustrate schematic representations of intermediate products and units for illustrating one embodiment of the embodiment as illustrated in FIG. 3.

FIG. 7 illustrates a schematic top view representation of an embedded wafer or production structure for illustrating a one embodiment of producing semiconductor devices or units.

FIG. 8 illustrates a schematic top view representation of a diagram for illustrating embodiments of producing semiconductor devices or units.

FIG. 9A,B illustrate schematic top view (A) and side view representations of a semiconductor device according to one embodiment.

FIG. 10A-D illustrate schematic top view representations of diagrams for illustrating embodiments of a method to produce semiconductor devices or units and the respective products obtained thereby.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

As employed in this Specification, the terms “coupled” and/or “electrically coupled” are not meant to mean that the elements must be directly coupled together; intervening elements may be provided between the “coupled” or “electrically coupled” elements.

The semiconductor chips described further below may be of different types, may be manufactured by different technologies and may include, for example, integrated electrical, electro-optical or electromechanical circuits and/or passives. The semiconductor chips may, for example, be configured as power semiconductor chips, such as power MOSFETs (Metal Oxide Semiconductor Field Effect Transistors), IGBTs (Insulated Gate Bipolar Transistors), JFETs (Junction Gate Field Effect Transistors), power bipolar transistors or power diodes. Furthermore, the semiconductor chips may include control circuits, microprocessors or microelectromechanical components. Semiconductor chips having a vertical structure may be involved, that is to say that the semiconductor chips may be fabricated in such a way that electric currents can flow in a direction perpendicular to the main surfaces of the semiconductor chips. A semiconductor chip having a vertical structure may have contact elements. for example, on its two main surfaces, that is to say on its top side and bottom side. Power semiconductor chips may have a vertical structure. By way of example, the source electrode and gate electrode of a power MOSFET may be situated on one main surface, while the drain electrode of the power MOSFET is arranged on the other main surface. Furthermore, the devices described below may include integrated circuits to control the integrated circuits of other semiconductor chips, for example, the integrated circuits of power semiconductor chips. The semiconductor chips need not be manufactured from specific semiconductor material, for example, Si, SiC, SiGe, GaAs, and, furthermore, may contain inorganic and/or organic materials that are not semiconductors, such as, for example, insulators, plastics or metals. Moreover, the semiconductor chips may be packaged or unpackaged.

In several embodiments layers or layer stacks are applied to one another or materials are applied or deposited onto layers. It should be appreciated that any such terms as “applied” or “deposited” are meant to cover literally all kinds and techniques of applying layers onto each other. They are meant to cover techniques in which layers are applied at once as a whole like, for example, laminating techniques as well as techniques in which layers are deposited in a sequential manner like, for example, sputtering, plating, molding, CVD, etc.

Furthermore the semiconductor chips described below may include contact elements or contact pads on one or more of their outer surfaces wherein the contact elements serve for electrically contacting the semiconductor chips. The contact elements may have any desired form or shape. They can, for example, have the form of lands, i.e. flat contact layers on an outer surface of the semiconductor package. The contact elements or contact pads may be made from any electrically conducting material, e.g., from a metal as aluminum, gold, or copper, for example, or a metal alloy, or an electrically conducting organic material, or an electrically conducting semiconductor material.

The semiconductor devices may include one or more electrically insulating layers. For example, the semiconductor chips may be covered with an electrically insulating material layer or encapsulation layer. The electrically insulating layers may cover any fraction of any number of surfaces of the components of the device, such as the carrier and the semiconductor chip integrated in the device. The electrically insulating layers may serve various functions. They may be used, for example, to electrically insulate components of the device from each other and/or from external components, but they may also be used as platforms to mount other components, for example, wiring layers or contact elements. The electrically insulating layers may be fabricated using various techniques, for example, using stencil printing, screen printing or any other appropriate printing technique. Furthermore, the electrically insulating layers may be deposited from a gas phase or a solution or may be laminated as foils. The electrically insulating layers may, for example, be made from organic materials, such as imide, epoxy or any kind of resin material or any kind of polymer material or other thermosetting materials, photoresist, silicon nitride, metal oxides, semiconductor oxides, ceramics or diamond-like carbon. The electrically insulating material can be applied, for example, by a casting process. Furthermore, a mold material may be used as the electrically insulating material. The mold material may be any appropriate thermoplastic or thermosetting material. Various techniques may be employed to cover the components with the mold material, for example, compression molding, injection molding, powder molding or liquid molding.

The semiconductor chips have electrodes (or contact pads) which allow electrical contact to be made with the integrated circuits included in the semiconductor chips. One or more metal layers may be applied to the electrodes of the semiconductor chips. The metal layers may be manufactured with any desired geometric shape and any desired material composition. The metal layers may, for example, be in the form of a layer covering an area. Any desired metal or metal alloy, for example, aluminum, titanium, gold, silver, copper, palladium, platinum, nickel, chromium or nickel vanadium, may be used as the material. The metal layers need not be homogenous or manufactured from just one material, that is to say various compositions and concentrations of the materials contained in the metal layers are possible. The electrodes may be situated on the active main surfaces of the semiconductor chips or on other surfaces of the semiconductor chips.

One or more metal layers may be placed over the semiconductor chip and/or the electrically insulating layers. The metal layers may, for example, be used to produce a redistribution layer. The metal layers may be used as wiring layers to make electrical contact with the semiconductor chips from outside the devices and/or to make electrical contact with other semiconductor chips and/or components contained in the devices. The metal layers may be manufactured with any desired geometric shape and any desired material composition. The metal layers may, for example, be composed of conductor tracks, but may also be in the form of a layer covering an area. Any desired metal, for example, aluminum, nickel, palladium, silver, tin, gold or copper, or metal alloy may be used as the material. The metal layers need not be homogenous or manufactured from just one material, that is to say various compositions and concentrations of the materials contained in the metal layers are possible. Furthermore, the metal layers may be arranged above or below or between electrically insulating layers.

The devices described below include external contact elements or external contact pads, which may be of any shape and size. The external contact elements may be accessible from outside the device and may thus allow electrical contact to be made with the semiconductor chips from outside the device. Furthermore, the external contact elements may be thermally conductive and may serve as heat sinks for dissipating the heat generated by the semiconductor chips. The external contact elements may be composed of any desired electrically conducting material, for example, of a metal, such as copper, aluminum or gold, a metal alloy or an electrically conducting organic material. Some of the external contact elements may be leads of a leadframe.

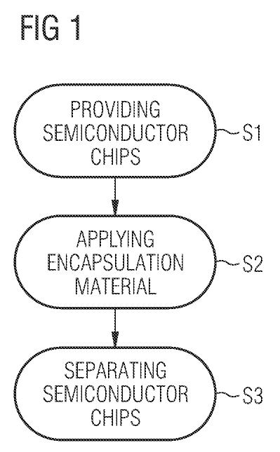

FIG. 1 illustrates a flow diagram of a method of producing at least two semiconductor devices according to an embodiment. The method includes providing at least two semiconductor chips (s1), applying an encapsulation material to the at least two semiconductor chips to form an encapsulation layer (s2), and separating the at least two semiconductor chips from each other to obtain at least two separated semiconductor devices (s3), wherein the outline of each one of the semiconductor devices includes three corners in total or more than four corners.

According to one embodiment, the separating line defines opposing side edges of the semiconductor devices obtained by the separation process. That means any space besides the separation line becomes part of either one of the semiconductor devices and there will be no intermediate space to become waste material. As a result, one advantage of the method is that the space of the embedded wafer is efficiently utilized and the amount of waste material is minimized.

According to one embodiment separating the at least two semiconductor chips includes at least one of sawing through the encapsulation layer, etching through the encapsulation layer, irradiating the encapsulation layer with electromagnetic radiation, irradiating the encapsulation layer with charged particles, stamping the encapsulation layer, and milling the encapsulation layer.

According to one embodiment separating the at least two semiconductor chips includes irradiating the encapsulation layer with a laser beam. The laser beam can be used to directly ablate the encapsulating material or, if possible, a stealth laser dicing technique can be employed wherein a laser beam that transmits through the wafer is focused beneath the surface, creating a row of perforations in a stealth dicing (SD) layer in or on the wafer.

According to an embodiment the method further includes applying the encapsulation material so that the semiconductor chips are evenly distributed throughout the encapsulation layer.

According to one embodiment the method further includes providing a plurality of semiconductor chips, in one embodiment more than two semiconductor chips, and separating the plurality of semiconductor chips from each other to obtain a plurality of separated semiconductor devices.

According to one embodiment the method further includes applying contact elements to a first main face of each one of the semiconductor devices.

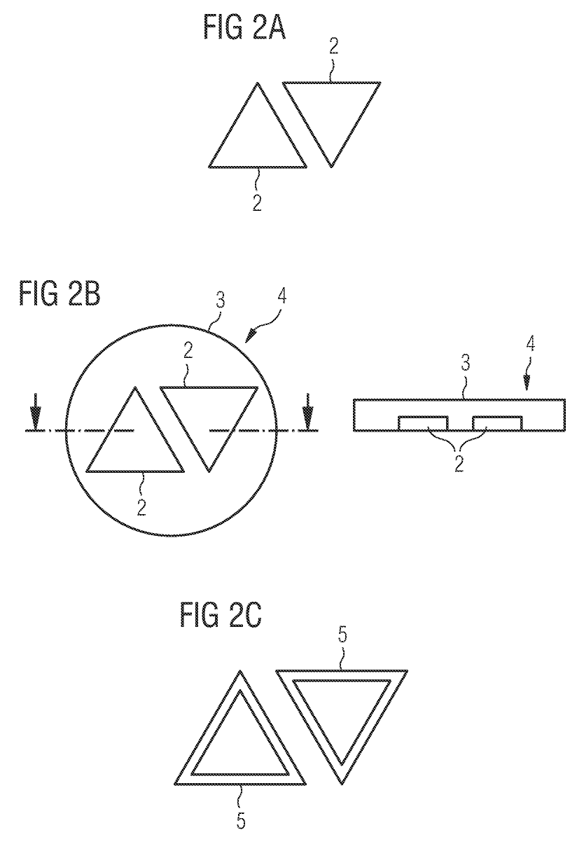

Referring to FIGS. 2A-C, there are illustrated schematic representations of intermediate products and semiconductor chips for illustrating an embodiment of the embodiment as illustrated in FIG. 1. FIG. 2A illustrates a top view of two semiconductor chips 2. The semiconductor chips 2 as illustrated each have an outline with a total of three corners. However, the semiconductor chips 2 can also have any other desired shape like, for example, a rectangular shape having four corners or a shape having five or more corners. FIG. 2B illustrates the formation of an encapsulation layer 3 including an encapsulation material. The left partial picture of FIG. 2B illustrates a top view of the semiconductor chips 2 and the encapsulation layer 3 and the right partial picture of FIG. 2B illustrates a cross-sectional side view of the semiconductor chips 2 and the encapsulation layer 3 from the dashed line of the left partial picture of FIG. 2B. It can be seen that the encapsulation layer 3 is formed to a wafer 4 having a circular shape. However, the wafer 4 can also have any other desired shape. FIG. 2C illustrates two semiconductor devices 5 obtained after separating the two embedded semiconductor chips 2 from each other. In one embodiment the outline of each one of the semiconductor devices 5 has three corners. However, the shape of the semiconductor devices 5 can also be such that their outline has more than four corners.

It is to be noted that the encapsulation material can be any sort of insulating material as was already outlined above. According to one embodiment the encapsulation material can be a mold material. According to one embodiment the encapsulation material can be formed of a laminate material.

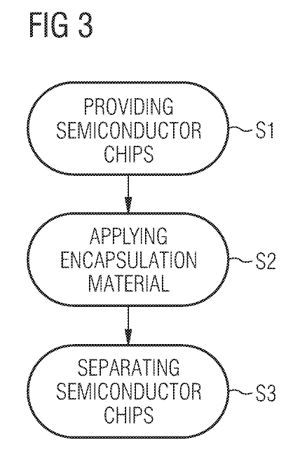

FIG. 3 illustrates a flow diagram of a method of producing at least two semiconductor devices according to one embodiment. The method includes providing at least two semiconductor chips (s1), applying an encapsulation material to the at least two semiconductor chips to form an encapsulation layer (s2), and separating the at least two semiconductor chips from each other by at least one of etching through the encapsulation layer, irradiating the encapsulation layer with electromagnetic radiation, irradiating the encapsulation layer with charged particles, stamping the encapsulation layer, and milling the encapsulation layer (s3).

According to one embodiment separating the at least two semiconductor chips includes irradiating the encapsulation layer with a laser beam either in a direct ablation technique or in a stealth dicing technique.

According to one embodiment the method further includes separating the at least two semiconductor chips from each other to obtain at least two separated semiconductor devices, wherein the outline of each one of the semiconductor devices includes three corners in total or more than four corners.

According to one embodiment, the separating of the semiconductor devices is carried out along a separation line defining opposing side edges of the semiconductor devices obtained by the separation process. That means any space besides the separation line becomes part of either one of the semiconductor devices and there will be no intermediate space to become waste material. As a result, one advantage of the method is that the space of the embedded wafer is efficiently utilized and the amount of waste material is minimized.

According to one embodiment the method further includes applying the encapsulation material so that the semiconductor chips are evenly distributed throughout the encapsulation layer.

According to one embodiment the method further includes providing a plurality of semiconductor chips, in one embodiment more than two semiconductor chips, and separating the plurality of semiconductor chips from each other to obtain a plurality of separated semiconductor devices.

According to one embodiment the method further includes applying contact elements to a first main face of each one of the semiconductor devices.

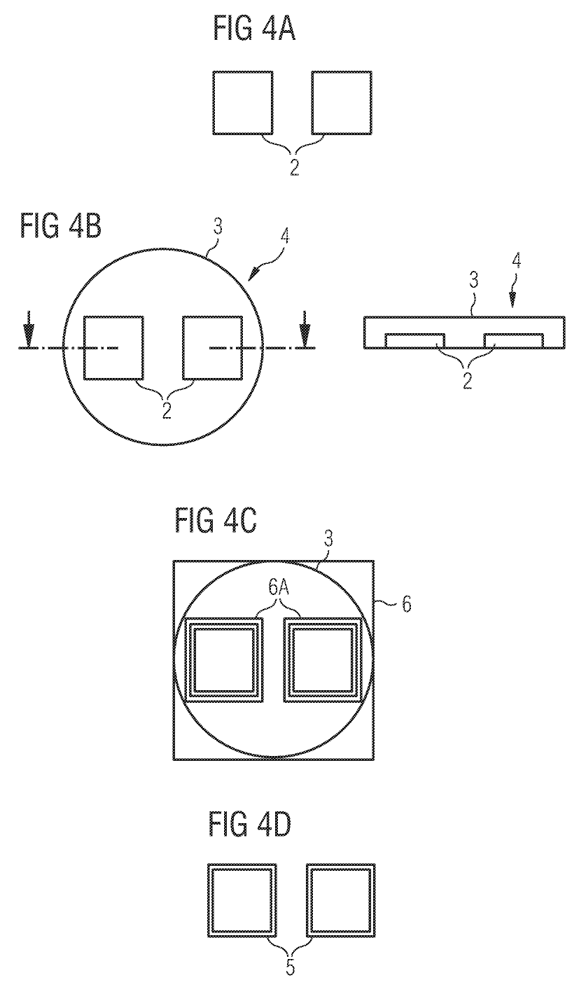

Referring to FIGS. 4A-D, there are illustrated schematic representations of intermediate products and semiconductor chips for illustrating an embodiment of the embodiment as illustrated in FIG. 3. FIG. 4A illustrates a top view of two semiconductor chips 2. The semiconductor chips 2 as illustrated each have an outline with a total of four corners. However, the semiconductor chips 2 can also have any other desired shape like, for example, a triangular shape having three corners or a shape having five or more corners. FIG. 4B illustrates the formation of an encapsulation layer 3 including an encapsulation material. The left partial picture of FIG. 4B illustrates a top view of the semiconductor chips 2 and the encapsulation layer 3 and the right partial picture of FIG. 4B illustrates a cross-sectional side view of the semiconductor chips 2 and the encapsulation layer 3 from the dashed line of the left partial picture of FIG. 4B. It can be seen that the encapsulation layer 3 is formed to a wafer having a circular shape. However, the wafer 4 can also have any other desired shape. FIG. 4C indicates a process of preparing the separating of the at least two semiconductor chips from each other. If the separation is carried out by etching, a mask 6 can be placed above the embedded wafer, the mask including openings 6A through which an etching material is applied to the embedded wafer to separate the semiconductor devices from each other. The mask 6 can also be used for a selective irradiation of the embedded wafer 4 with electromagnetic irradiation or with charged particles through the mask openings 6A. Alternatively the mask 6 can be omitted and instead a laser beam can be used for direct structuring or ablating the encapsulation material or structuring it by use of the stealth dicing technique. FIG. 4D illustrates two semiconductor devices 5 obtained after separating the two embedded semiconductor chips from each other. In this embodiment the outline of each one of the semiconductor devices 5 has four corners. However, the shape of the semiconductor devices 5 can also be such that their outline has three corners or more than four corners, respectively.

It is to be noted that the encapsulation material can be any sort of insulating material as was already outlined above. In one embodiment the encapsulation material can be a mold material. According to one embodiment the encapsulation material can be formed of a laminate material.

FIG. 5 illustrates a flow diagram of a method of producing at least two units according to one embodiment. The method includes providing a production structure (s1), producing at least two units on the production structure (s2), separating the at least two units from each other to obtain at least two separated units (s3), wherein the separating is carried out along a line defining opposing side edges of the unit.

The production structure can be, for example, any sort of substrate or layer with the exception of a semiconductor wafer. The substrate or layer can, for example, be a laminate substrate or laminate layer, a dielectric layer, an insulating board like a printed circuit board (PCB). On such a substrate units like, for example, any sort of devices, in one embodiment electrical, electronic, electromechanical, micro-mechanical, electro-optical or micro-optical devices or circuits can be fabricated or produced.

According to one embodiment of the method one outline of each one of the units cannot be linearly continued without destroying another unit of the production unit. That means the units are arranged with respect to each other on the production unit so that they each include a particular number of corners. The units are further arranged such that at a corner of a unit the separation process of the unit cannot be linearly extended beyond the corner without destroying an adjacent unit.

According to one embodiment of the method the outline of each one of the units includes three corners in total or more than four corners. According to one embodiment the unit are shaped as hexagons.

According to one embodiment of the method separating the at least two units includes at least one of sawing through the production structure, etching through the production structure, irradiating the production structure with electromagnetic radiation, irradiating the production structure with charged particles, stamping the production structure, and milling the production structure.

According to one embodiment of the method separating the at least two units includes irradiating the production structure with a laser beam.

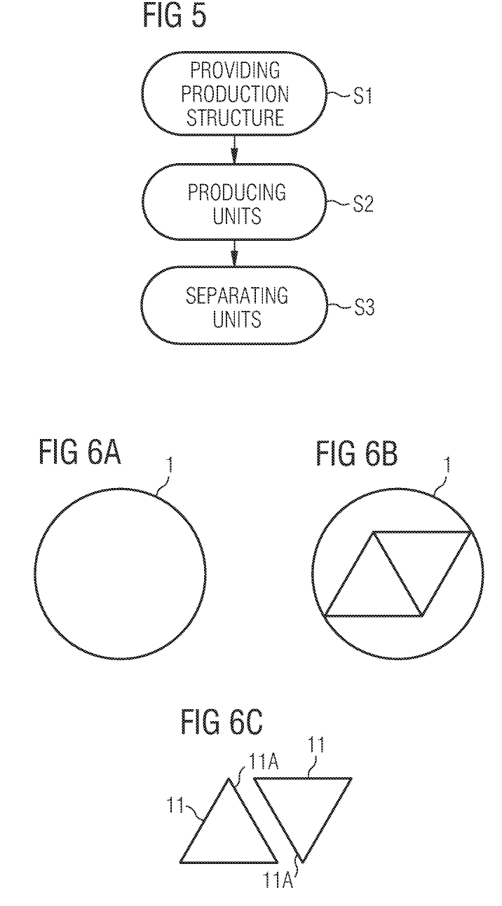

Referring to FIGS. 6A-C, there are illustrated schematic representations of intermediate products and units for illustrating one embodiment of the embodiment as illustrated in FIG. 5. FIG. 6A illustrates a top view of a production structure 1 which has the form of a wafer. However, the production structure 1 can have any desired form and diameter. On the production structure 1 two production units 11 are produced which can be made of any sort of devices as was outlined above. FIG. 6B illustrates the outlines of the production units. The separation process can be carried out along a line defining opposing side edges 11A of the production units 11. FIG. 6C illustrates the separated production units 11.

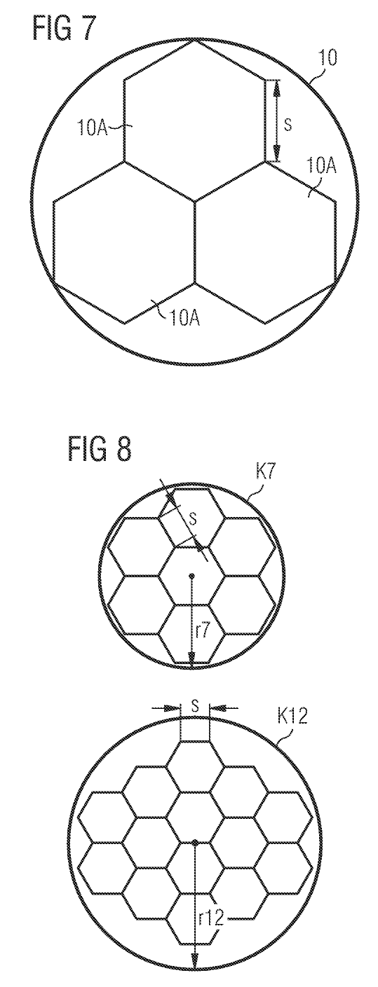

Referring to FIG. 7, there is illustrated a schematic top view representation of an embedded wafer or a production structure for illustrating one embodiment of producing semiconductor devices or other units. The wafer 10 can either be an embedded wafer such as that depicted in FIGS. 2A-C and FIGS. 4A-D and designated with reference sign 4 or it can be a production structure such as that depicted in FIGS. 6A-C. According to one embodiment the wafer 10 is an embedded wafer and semiconductor devices are to be produced. According to another embodiment the wafer 10 is a production structure and production units are to be produced. In any case the lines 10A designate the boundaries of the semiconductor devices or production units to be produced. It can be seen that the outline of the devices or units to be produced include a total of six corners and the shape of a regular hexagon. In the embodiment of FIG. 7 a total of three hexagons is arranged within the wafer 10 wherein r=2s with r the radius of the wafer 10 and s the length of a side edge of a hexagon. It can also be seen that the hexagons are arranged with adjacent boundaries so that there is no intermediate space between the hexagons to become waste material. In this way the amount of waste material can be minimized which was outlined above.

Referring to FIG. 8, there is illustrated a schematic top view representation of a construction diagram for illustrating further embodiments of producing semiconductor devices or production units. It can be seen that the arrangement of as many as possible devices or units within a wafer is an optimization problem. The diagram of FIG. 8 illustrates an arrangement of regular hexagons arranged with adjacent boundaries with no intermediate space in between. In dependence of the area of the wafer different numbers of devices or units can be arranged within the wafer. There are illustrated two different circular wafers (bold lines) having different radii r, namely r7 and r12. It can be seen that in order to arrange 7 devices or units within a wafer K7 with minimum waste, the relationship between radius r7 of the wafer and length s of the hexagons side edge should be r7=s33 √7. In order to arrange 12 devices or units within a wafer K12 with minimum waste, the relationship between radius r12 of the wafer and length s of the hexagons side edge should be r12=s×√19.

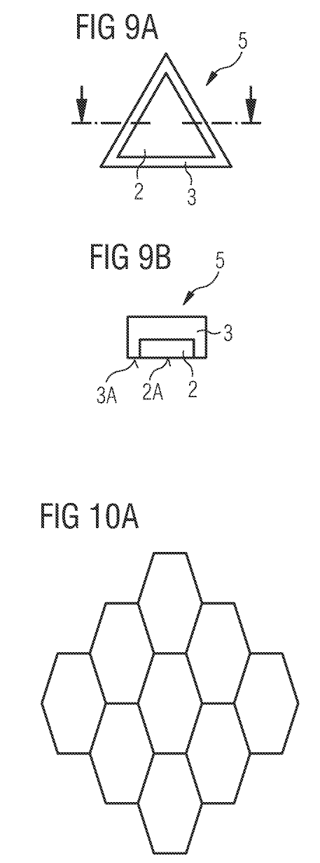

FIG. 9A, B illustrate schematic top view (A) and cross-sectional side view (B) representations of a semiconductor device according to an embodiment. The semiconductor device 5 includes a semiconductor chip 2 having a first main face 2A, an encapsulation layer embedding the semiconductor device, the encapsulation layer having a first main face 3A, wherein the outline of the first main face 3A of the encapsulation layer 3 is shaped to have three corners in total. In one embodiment illustrated in FIGS. 9A, B the semiconductor chip 2 also includes an outline having a total of three corners. However, it will be appreciated that the outline of the semiconductor chip 2 can also have any other shape, in one embodiment a shape including four corners or more than four corners. Furthermore, the semiconductor device 5 can also have an outline including more than four corners.

According to one embodiment the semiconductor device 5 further includes an array of contact elements attached to a first main face of the semiconductor device 5 or to a second main face opposed to the first main face. According to one embodiment the contact elements are solder bumps or solder balls.

According to one embodiment of the semiconductor device 5, the first main face 2A of the semiconductor chip 2 is coplanar with the first main face 3A of the encapsulation layer 3.

According to one embodiment of the semiconductor device 5, the outline of the first main face 2A of the semiconductor chip 2 is shaped to have three corners in total or more than four corners.

According to one embodiment of the semiconductor device 5, the semiconductor device 5 further includes a redistribution layer applied to a main face of the encapsulation layer 3.

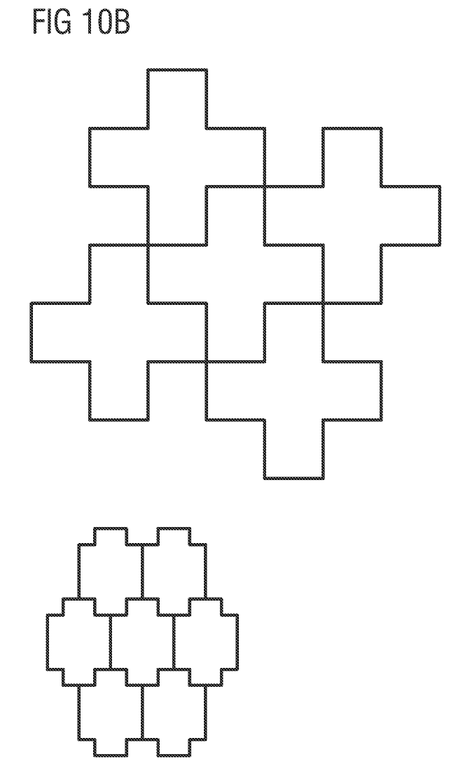

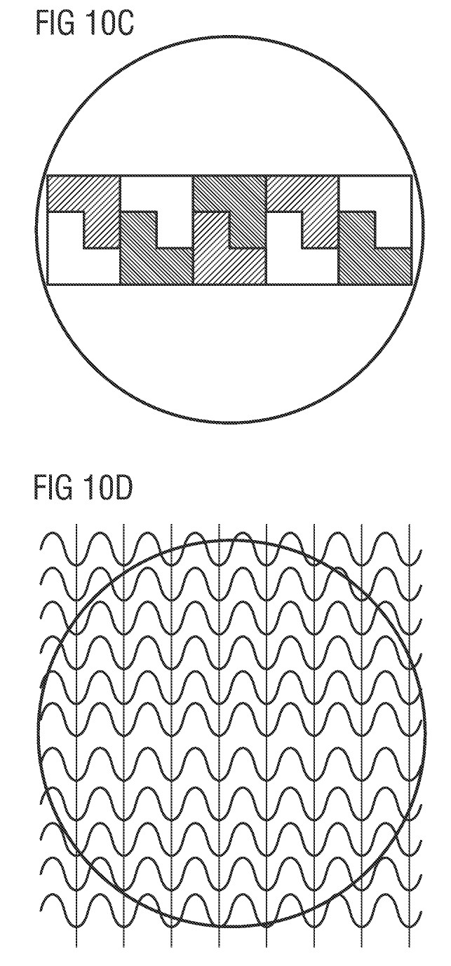

FIG. 10A-D illustrate schematic top view representations of diagrams for illustrating further embodiments of a method to produce semiconductor devices or units and the respective products obtained thereby. All the structures illustrated can be utilized to produce semiconductor chips, semiconductor devices or units of the respective shape. The semiconductor devices can have the same cross-sectional structure as that illustrated in FIG. 9A. It will be noted that in all these embodiments the chips, devices or units are arranged on the wafer with boundaries adjacent to each other leaving no intermediate spaces between them. As mentioned also semiconductor chips can be produced from a semiconductor wafer as indicated in one of FIGS. 10A-D.

FIG. 10A illustrates an array of irregular hexagons. FIG. 10B, upper and lower partial pictures, illustrate different forms of arrays of cross forms. FIG. 10C illustrates an array of corners arranged within a wafer form. FIG. 10D illustrates an array of sinus Figures.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of producing at least two semiconductor devices, comprising:
providing at least two semiconductor chips;
applying an encapsulation material to the at least two semiconductor chips to form an encapsulation layer; and
separating the at least two semiconductor chips from each other to obtain at least two separated semiconductor devices, wherein the outline of each one of the semiconductor devices comprises three corners in total or more than four corners.

2. The method of claim 1, further comprising:
separating the at least two semiconductor chips having at least one of sawing through the encapsulation layer, etching through the encapsulation layer, irradiating the encapsulation layer with electromagnetic radiation, and irradiating the encapsulation layer with charged particles, stamping the encapsulation layer, and milling the encapsulation layer.

3. The method of claim 2, wherein separating the at least two semiconductor devices comprises irradiating the encapsulation layer with a laser beam.

4. The method of claim 1, further comprising:
applying the encapsulation material so that the semiconductor chips are evenly distributed throughout the encapsulation layer.

5. The method of claim 1, further comprising:
providing a plurality of semiconductor chips, more than two semiconductor chips, and
separating the plurality of semiconductor chips from each other to obtain a plurality of separated semiconductor devices.

6. The method of claim 1, further comprising:
applying contact elements to a first main face of each one of the semiconductor devices.

7. A method of producing at least two semiconductor devices, comprising:
providing at least two semiconductor chips;
applying an encapsulation material to the at least two semiconductor chips to form an encapsulation layer; and
separating the at least two semiconductor chips from each other by at least one of sawing through the encapsulation layer, etching through the encapsulation layer, irradiating the encapsulation layer with electromagnetic radiation, irradiating the encapsulation layer with charged particles, stamping the encapsulation layer, and milling the encapsulation layer.

8. The method of claim 7, wherein separating the at least two semiconductor devices comprises irradiating the encapsulation layer with a laser beam.

9. The method of claim 7, further comprising:
separating the at least two semiconductor chips from each other to obtain at least two separated semiconductor devices, wherein the outline of each one of the semiconductor devices comprises three corners in total or more than four corners.

10. The method of claim 7, further comprising:
applying the encapsulation material so that the semiconductor chips are evenly distributed throughout the encapsulation layer.

11. The method of claim 7, further comprising:
providing a plurality of semiconductor chips, more than two semiconductor chips, and
separating the plurality of semiconductor chips from each other to obtain a plurality of separated semiconductor devices.

12. The method of claim 7, further comprising:
applying contact elements to a first main face of each one of the semiconductor devices.

13. A method of producing at least two units, comprising:
providing a production structure;
producing at least two units on the production structure; and
separating the at least two units from each other to obtain at least two separated units, wherein the separating is carried out along a line defining opposing side edges of the unit.

14. The method of claim 13, comprising wherein one outline of each one of the units cannot be linearly continued without destroying another unit of the production unit.

15. The method of claim 13, wherein the outline of each one of the units comprises three corners in total or more than four corners.

16. The method of claim 13, wherein separating the at least two units comprises at least one of sawing through the production structure, etching through the production structure, irradiating the production structure with electromagnetic radiation, irradiating the production structure with charged particles, stamping the production structure, and milling the production structure.

17. The method of claim 16, wherein separating the at least two units comprises irradiating the production structure with a laser beam.

18. A semiconductor device, comprising:
a semiconductor chip having a first main face; and
an encapsulation layer embedding the semiconductor chip, the encapsulation layer having a first main face;
wherein the outline of the first main face of the encapsulation layer is shaped to have three corners in total or more than four corners.

19. The semiconductor device of claim 18, further comprising:
an array of contact elements attached to a first main face of the semiconductor device or to a second main face opposed to the first main face.

20. The semiconductor device of claim 19, comprising wherein the contact elements are solder bumps or solder balls.

21. The semiconductor device of claim 18, comprising wherein the first main face of the semiconductor chip is coplanar with the first main face of the encapsulation layer.

22. The semiconductor device of claim 18, comprising shaping the outline of the first main face of the semiconductor chip to have three corners in total or more than four corners.

23. A semiconductor device, comprising:
a first main face having an outline shaped to have the form of one of a cross, a corner, an irregular hexagon, or a sinus.

24. The semiconductor device of claim 23, further comprising:
an array of contact elements attached to the first main face of the semiconductor device.
